(19) United States
(12) Patent Application Publication
(10) Pub. No.: US 2014/0182513 A1
(43) Pub. Date: Jul. 3, 2014

(54) HYBRID SCREENING NOZZLE

(71) Applicant: International Business Machines Corporation, (US)

(72) Inventors: William Wayne Harkins, Montgomery, NY (US); Christos Theodore Kapogiannis, Pleasant Valley, NY (US); Robert Weiss, LaGrangeville, NY (US)

(73) Assignee: INTERNATIONAL BUSINESS MACHINES CORPORATION, ARMONK, NY (US)

(21) Appl. No.: 13/733,167

(22) Filed: Jan. 3, 2013

(51) Int. Cl. H01L 21/48

(52) U.S. Cl. CPC H01L 21/4814
USPC 118/406; 222/566

(57) ABSTRACT

An extrusion nozzle for applying a paste to a green sheet. The nozzle having a center orifice with a leading edge and a trailing edge. The leading edge comprising a tip having a durometer value of about 40 D shore. The leading edge may comprise a urethane material. The trailing edge may either be a carbide rod or it may comprise a material with a durometer value of about 60 D shore. The trailing edge may also comprise a urethane material. The urethane material may be molded onto the nozzle and ground down to meet the specifications required for the application of the paste.

### FIELD OF INVENTION

This disclosure relates generally to the field of multilayer ceramic screening. Specifically to a screening nozzle for applying a paste to a green sheet.

### DESCRIPTION OF RELATED ART

Multilayer ceramic (MLC) semiconductor packages are formed by stacking and bonding together flexible paper like sheets commonly referred to as ceramic green sheets. Green sheet segments of desired size and configuration are punched to provide via holes and, by a screen printing technique, a conductive paste (which may be a copper paste) fills the via holes and/or a conductive circuit pattern is applied to the face of the green sheet as required. Such green sheets, after screening, are assembled in a stack, pressed, and subsequently sintered in an oven at a relatively high temperature. Upon sintering, the vehicle and any binder material are burned off with the remaining rigid unitary ceramic body provided with interior interconnected conductive patterns. Additional processing occurs prior to the units being encapsulated.

Critical to the MLC manufacturing process is the screening operation. Screening is performed by extruding the paste from a paste tube though a metal mask to create the circuit pattern lines and to fill vias in the green sheets. The ceramic green sheets are relatively fragile, with a thickness that may be on the order of 0.006 inches up to 0.0020 inches with the typical size being 0.008 inches, and a surface area that is relatively large compared to the thickness. Particular problems are encountered when screening such relatively soft and deformable, paper-thin, flexible green sheets, which are of no concern to the general screen printing art utilizing rigid substrates.

To apply the paste onto the green sheets the paste is extruded using a pressurized copper paste from a set of carbide rod nozzle tips though a metal mask to create fine line patterns and filled vias. The carbide rod nozzle tips are held firmly against the metal mask and pressurized copper paste is extruded through the mask while the nozzle assembly moves across the mask/greensheet.

A common defect encountered in the screening process is the formation and progression of copper paste build-up on the electroform masks. Paste build-up begins as bright colored burnishing marks on the mask's surface caused by the scoring action of the leading carbide rod nozzle tip traveling across the mask surface during each screening pass. As the screening passes increase, copper paste begins to bond to the burnished spots, and the copper paste build-up spreads across the mask's surface eventually bridging over vias and causing open via defects on the screened greensheets.

Because the electroform masks are cleaned following each screened greensheet pass, the leading edge carbide rod nozzle tip further scores wider areas of the cleaned mask surface leading to larger areas of burnishing and more paste buildup.

While traditional mask cleaning techniques using highly pressurized TMAH, electrified TMAH and DI Water sprays are sufficient for general mask cleaning, these techniques are ineffective at dislodging copper paste build-up. When vias become clogged, the electroform masks must be scrapped and replaced with new identically patterned masks. With an approximate cost being significant, the problem becomes two-fold; first, mask scrapping significantly effects the Screening sector's “cost-to-manufacture” and secondly, multiple duplicate masks must be stored in inventory since the original mask with paste build-up is un-repairable.

### SUMMARY

According to one embodiment of the present invention, an extrusion nozzle is contemplated comprising a center extrusion orifice to allow for the flow of paste. A leading edge fabricated from a first urethane tip is introduced to prevent the paste from extruding in front of the nozzle. A trailing edge fabricated from a carbide tip is utilized to force the paste through the mask and onto a green sheet. The urethane tip may have a durometer value less than about 60 D shore. Preferably the urethane tip has a durometer value of about 40 D shore.

According to another embodiment of the present invention, an extrusion nozzle is contemplated having a center extrusion orifice to allow for the flow of paste. A leading edge fabricated from a urethane tip is introduced to prevent the paste from extruding in front of the nozzle. A trailing edge is fabricated from a second urethane tip. By utilizing urethane for both the leading and trailing edge of the nozzle the likelihood of burnishing the mask is diminished. The first urethane tip may have a durometer value less than about 60 D shore. Preferably the urethane tip has a durometer value of about 40 D shore. The second urethane tip may have a durometer value of greater than 30 D shore but less than 75 D shore and preferably 60 D shore. The extrusion nozzles may be produced by molding the urethane tips onto the nozzle. A dovetail may be formed or milled into the nozzle to provide greater retention of the urethane tips.

According to another embodiment of the present invention, an extrusion nozzle is contemplated having a center extrusion orifice to allow for the flow of paste, a leading edge comprising a first tip having a durometer value less than 60 D shore and a trailing edge comprising a second tip having a durometer value greater than 30 D shore. The leading edge preferably has a durometer value of 40 D shore and the trailing edge has a durometer value of 60 D shore. The materials maybe molded onto the extrusion nozzle. A dovetail may be formed or milled into the nozzle to provide greater retention of the tips.

According to another embodiment of the present invention, an assembly for screening a multilayer ceramic with a conductive paste is contemplated, comprising, a paste cartridge containing the conductive paste. The assemble having a cartridge block, the top of the cartridge block being configured to receive the paste cartridge. The cartridge block comprising a paste routing section, the paste routing section comprising a flared section located at a bottom of the cartridge block. A pneumatic fitting is attached to the paste cartridge, the pneumatic fitting is configured to pressurize the conductive paste in the paste cartridge such that the conductive paste is extruded from the paste cartridge into the cartridge block through the paste routing section of the cartridge block by the pressure from the pneumatic fitting. An extrusion nozzle comprising a center extrusion orifice, a leading edge comprising a first tip having a durometer value of less than 60 D shore and a trailing edge comprising a second tip having a durometer value of greater than 40 D shore, is connected to the flared section of the cartridge block. The nozzle is configured to receive the conductive paste from the flared section, and screen the conductive paste onto the multilayer ceramic through the nozzle.

The first tip may be of a urethane material to allow the first tip to be molded onto the nozzle. The second tip may either be a carbide rod, or it may be a urethane or other material having a durometer value of greater than 40 D shore. The first tip and second tip may be molded onto the nozzle and secured with a dovetail formed in the nozzle.

### BRIEF DESCRIPTION OF THE SEVERAL VIEWS OF THE DRAWINGS

FIG. 1A illustrates a front view of an embodiment of an MLC screening assembly including a cartridge block, paste cartridge, pneumatic fitting, and nozzle.

FIG. 1B illustrates a side view of an embodiment of an MLC screening assembly.

FIG. 2A illustrates front view of an embodiment of a nozzle

FIG. 2B illustrates a view along sections x-x′ of FIG. 2A.

FIG. 3 illustrates a means for mounting the urethane tip to the nozzle.

### DETAILED DESCRIPTION

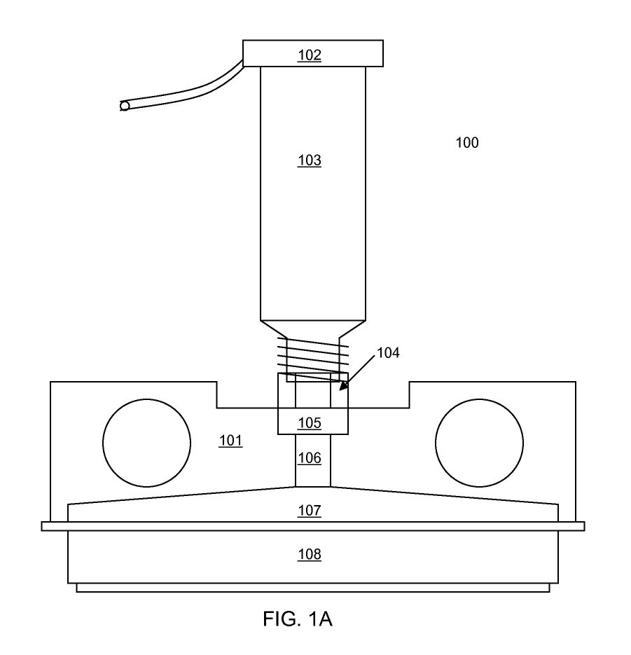

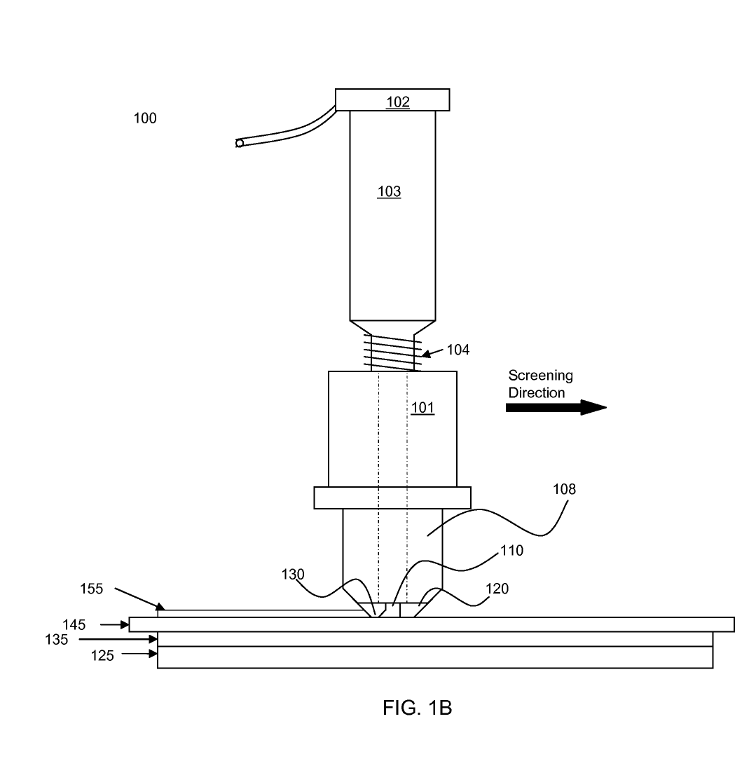

FIG. 1A illustrates a front view of an embodiment of an MLC screening assembly 100 including a cross section of a cartridge block 101, a paste cartridge 103, a pneumatic fitting 102, and a nozzle 108. Pneumatic fitting 102 attaches to the top of paste cartridge 103, and acts to pressurize the paste in paste cartridge 103 and force the paste out of the cartridge 103 and into the paste routing section of the cartridge block 101. Pneumatic fitting 102 may comprise a quick-connect pneumatic fitting. Paste cartridge 103 may comprise a cylindrical plastic paste cartridge filled with a conductive paste (such as a copper paste) for MLC screening; the paste cartridge 103 may be used to store the conductive paste after manufacture. Paste cartridge 103 attaches to paste cartridge attachment nipple 104, which is attached to threaded cartridge attachment 105. When pneumatic fitting 102 pressurizes and forces paste out of paste cartridge 103, the paste travels from paste cartridge 103 via paste cartridge attachment nipple 104 and threaded cartridge attachment 105 through hole 106 and flared section 107 to nozzle 108. Flared section 107 causes the paste to flare out and fill a screening surface of the nozzle 108. The paste is then screened onto a ceramic substrate through the nozzle 108. The dimensions of flared section 107 are commensurate with the dimensions of nozzle 108.

FIG. 1B illustrates a side view of an embodiment of an MLC screening assembly. The MLC screening assembly 100 is shown moving in a direction from left to right upon a mask 145. Paste 155 is extruded through a central orifice 110. The leading edge 120 prevents the paste 155 from pushing forward onto mask 145 in front of nozzle 108. Leading edge 120 needs to be of sufficient hardness to prevent paste 155 from protruding forward onto mask 145. However, as the inventors have determined if leading edge 120 is too hard it may lead to scoring of the mask surface leading to areas of burnishing and paste buildup. Trailing edge 130 causes paste 155 to be forced through mask 145 onto green sheet 135. Trailing edge 130 must be of sufficient hardness to force the paste through the mask 145.

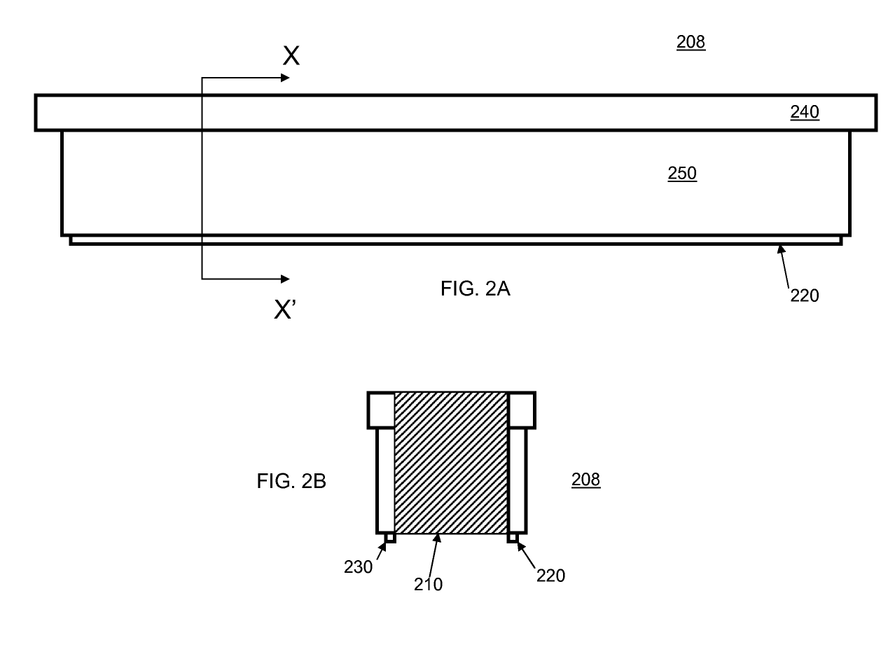

FIG. 2A illustrates a front view of an embodiment of nozzle 208. Nozzle 208 includes a fastening means 240 to fasten nozzle 208 to a cartridge block such as block 101 of FIG. 1. Nozzle 208 includes a center section 250 which may have leading and trailing edges 220 and 230 respectively. The nozzle 208 may be milled from a single block of stainless steel or other material.

FIG. 2B illustrates a side view of an embodiment of nozzle 208 along section x-x′. Nozzle 208, includes center extrusion orifice 210, which allows the paste to be applied to the mask and green sheets. The extrusion nozzle further has a leading edge 220 and a trailing edge 230. The leading edge 220 may comprise a urethane tip. The prior art nozzles would have comprised a carbide rod. In the prior art nozzle having a leading edge comprising a carbide rod caused burnishing of the mask. This is due in part to the leading edge not being lubricated by the paste as the trailing edge is. In addition, imperfections or damage to the carbide rod will cause more damage due to the hardness of the rod compared to the mask. Whereas in the present invention, the leading edge 220, is softer than the mask material. Therefore the inventors have determined that a urethane tip for leading edge 110 may lessen the possibility of burnishing of the mask. The urethane of leading edge may have a hardness measured as a durometer value of less than 60 D shore. In one embodiment a urethane with a durometer value of 40 D shore may be preferred. While a urethane material is taught it should be understood that other materials may be utilized provide the shore value is less than about 60 D shore and preferably about 40 D shore.

The trailing edge 230 of nozzle 208 may comprise a carbide tip as in the prior art nozzle. In an alternative embodiment the trailing edge 230 may comprise a urethane tip. The urethane material used for the trailing edge 230 may have has a durometer value greater than 30 D shore but less than 75 D shore, preferably 60 D shore. While a urethane tip is disclosed for trailing edge 230, it is possible to utilize alternative materials provided the durometer value of the material has a value in the ranges described above.

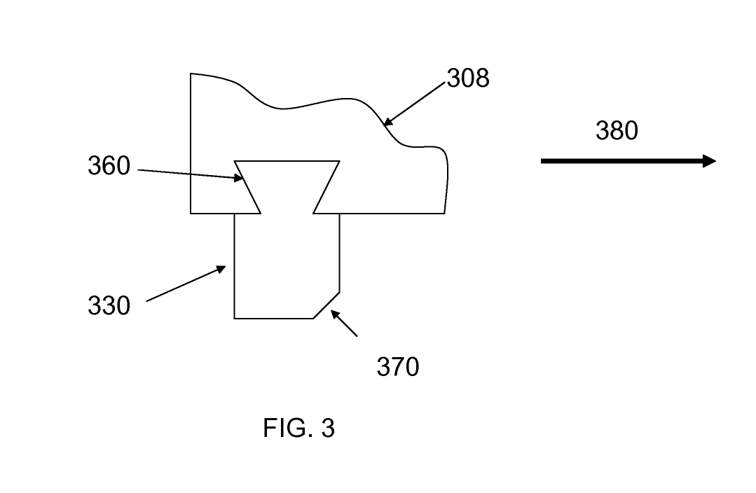

FIG. 3 illustrates a means for mounting the urethane tip 330 to the nozzle 308. By utilizing a dovetail cut out 360, urethane tip 330 may be molded onto and into the nozzle 308, holding the tip 330 securely to nozzle 308. Once molded the tip 330 is ground to a rectangular shape. A leading edge 370 may be ground onto the tips 330 to allow for smoother flow across the greensheets, and lessens the possibility of pulling the paste out of the mask. The leading edge 370 may be at a 45 degree angle to the green sheets. The nozzle 308 moves in a left to right direction as indicted by the direction of travel 380.

In addition by utilizing a dovetail cut out 360 to mount urethane tip 330, when worn the tips 330 may be replaced by melting the old tip 330 to remove them and replacing as described above. The inventors have noted that during normal operation of a prior art nozzles, the carbide tips wear and flatten, which results in the need to replace the entire nozzle assembly. By utilizing the dovetail 360, it is possible to replace the urethane tip 330 when wear occurs, thus increasing the life of the nozzle 308. In addition in the event of uneven wear or damage to the tip 330, the tip may be ground to meet the specifications multiple times, again increasing the life of the nozzle 308.

The terminology used herein is for the purpose of describing particular embodiments only and is not intended to be limiting of the invention. As used herein, the singular forms “a”, “an”, and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

1. An extrusion nozzle comprising:
a center extrusion orifice;
a leading edge comprising a urethane tip; and
a trailing edge comprising a carbide tip.

2. The extrusion nozzle of claim 1 wherein the urethane tip has a durometer value less than about 60 D shore.

3. The extrusion nozzle of claim 1 wherein the urethane tip has a durometer value of about 40 D shore.

4. An extrusion nozzle comprising:
a nozzle having a center extrusion orifice;
a leading edge comprising a first urethane tip; and
a trailing edge comprising a second urethane tip.

5. The extrusion nozzle of claim 4 wherein the first urethane tip has a durometer value less than about 60 D shore.

6. The extrusion nozzle of claim 4 wherein the first urethane tip has a durometer value of about 40 D shore.

7. The extrusion nozzle of claim 4 wherein the second urethane tip has a durometer value greater than 30 D shore but less than 75 D shore.

8. The extrusion nozzle of claim 6 wherein the second urethane tip has a durometer value greater than 30 D shore but less than 75 D shore.

9. The extrusion nozzle of claim 4 wherein the first and second urethane tip are molded to the nozzle.

10. The extrusion nozzle of claim 4 wherein the first and second urethane tip are molded to the nozzle with a dovetail.

11. An extrusion nozzle comprising:
a nozzle having a center extrusion orifice;
a leading edge comprising a first tip having a durometer value less than 60 D shore; and
a trailing edge comprising a second tip having a durometer value more than 30 D shore.

12. The extrusion nozzle of claim 11 wherein the first tip has a durometer value of about 40 D shore.

13. The extrusion nozzle of claim 12 wherein the second tip has a durometer value of about 60 D shore.

14. The extrusion nozzle of claim 11 wherein the first and second tip are molded to the nozzle.

15. The extrusion nozzle of claim 11 wherein the first and second tip are molded to the nozzle with a dovetail.

16. An assembly for screening a multilayer ceramic with a conductive paste, comprising:
a paste cartridge containing the conductive paste;
a cartridge block, a top of a cartridge block being configured to receive the paste cartridge, the cartridge block comprising a paste routing section, the paste routing section comprising a flared section located at a bottom of the cartridge block;
a pneumatic fitting attached to the paste cartridge, the pneumatic fitting configured to pressurize the conductive paste in the paste cartridge such that the conductive paste is extruded from the paste cartridge into the cartridge block through the paste routing section of the cartridge block by the pressure from the pneumatic fitting; and
an extrusion nozzle comprising a center extrusion orifice, a leading edge comprising a first tip having a durometer value of less than 60 D shore and a trailing edge comprising a second tip having a durometer value of greater than 40 D shore, connected to the flared section of the cartridge block, the nozzle configured to receive the conductive paste from the flared section, and screen the conductive paste onto the multilayer ceramic through the nozzle.

17. The assembly for screening a multilayer ceramic with a conductive paste of claim 16 wherein the first and second tip are mounted to the nozzle with a dovetail.

18. The assembly for screening a multilayer ceramic with a conductive paste of claim 16 wherein the first tip comprises urethane and the second tip comprises carbide steel.

19. The assembly for screening a multilayer ceramic with a conductive paste of claim 16 wherein the first tip comprises urethane and the second tip comprises urethane.

20. The assembly for screening a multilayer ceramic with a conductive paste of claim 19 wherein the second tip has a durometer value greater than 60 D shore but less than 75 D shore.

21. The assembly for screening a multilayer ceramic with a conductive paste of claim 20 wherein the first tip has a durometer value of about 40 D shore.

22. The assembly for screening a multilayer ceramic with a conductive paste of claim 16 wherein the first and second tip are molded to the nozzle with a dovetail.
